(19) United States
(12) Patent Application Publication
(10) Pub. No.: US 2018/0235078 A1
(43) Pub. Date: Aug. 16, 2018

(54) ELECTROMAGNETIC SHIELDING STRUCTURE FOR ELECTRONIC BOARDS

(71) Applicant: COMMISSARIAT À L'ÉNERGIE ATOMIQUE ET AUX ÉNERGIES ALTERNATIVES, Paris (FR)

(72) Inventors: Jean-Pierre Simonato, Sassenage (FR); Caroline Celle, Firminy (FR)

(21) Appl. No.: 15/894,011

(22) Filed: Feb. 12, 2018

(30) Foreign Application Priority Data
Feb. 13, 2017 (FR) 17 51162

(51) Int. Cl. H05K 1/02; H05K 1/18; H05K 3/46; H05K 3/28

(52) U.S. Cl. CPC H05K 1/0218; H05K 1/18; H05K 2201/0723; H05K 3/28; H05K 1/0274; H05K 3/4644

(57) ABSTRACT

An electromagnetic shielding structure comprising successively: an electrically insulating layer of a first polymeric material, an electrically conductive shielding film comprising at least 90 mass % of metal nanowires, and a protective layer of a second polymeric material.

### CROSS-REFERENCE TO RELATED APPLICATIONS

This application claims priority from French Patent Application No. 17 51162 filed on Feb. 13, 2017. The content of this application is incorporated herein by reference in its entirety.

### TECHNICAL FIELD AND STATE OF PRIOR ART

The present invention relates to an electromagnetic shielding structure for electronic boards and a method for making it.

Electronic boards or printed circuits are formed with different electronic components, such as microprocessors, memories, or buses, for example, disposed on a wafer and electrically connected to each other. To protect the electronic components from the electromagnetic field, radiofrequencies and electrical interference, an electromagnetic shielding is deposited onto the electronic board. The electromagnetic shielding forms an electrically conductive physical barrier, between the electromagnetic source and the potentially sensitive elements to be protected.

Shielding devices are, conventionally, in the form of shielding cases (also called shielding “cages”). The cases are made by using metal sheets or metal grids which cover the sensitive elements. The cases can be fastened to the electronic boards, for example with fastening or screwing clips, or even through welding. These fastening systems generally require a complex and time-consuming implementation.

Furthermore, this type of cases has a quite important overall space and is rather adapted for electronic boards having a planar area and a simple, for example square or rectangular, geometrical shape.

### DISCLOSURE OF THE INVENTION

Consequently, a purpose of the present invention is to provide a space-saving and lightweight electromagnetic shielding structure.

Another purpose of the present invention is to provide a shielding structure which can be disposed on electronic boards with various sizes and shapes.

These purposes are achieved by an electromagnetic shielding structure comprising, and preferably consisting of, successively:
an electrically insulating layer of a first polymeric material,
an electrically conductive shielding film comprising at least 90 mass % of metal nanowires,
a protective layer of a second polymeric material.

By “polymeric material”, it is meant a material formed by a polymer or a copolymer.

The nanowires form a semi-transparent electrically conductive percolating network. By percolating network, it is meant that the nanowires form a continuous path throughout the shielding film so as to be able to electrically conduct charges from end to end of the shielding film. By semi-transparent, it is meant that the network of nanowires has a transmittance higher than 50% in the visible region, i.e. from 350 nm to 750 nm, and preferably higher than 70% in the visible region.

The shielding film contains at least 90% of metal nanowires. It can contain up to 10 mass % of additional elements. The additional elements are electrically conductive.

According to a first alternative, the shielding film further comprises carbon and/or graphene nanotubes.

According to another alternative, the shielding film consists of metal nanowires.

Advantageously, the shielding film has a thickness ranging from 20 nm to 1 000 nm and preferably from 20 nm to 300 nm.

The nanowires are nanowires of a noble metal, or an alloy of noble metals, a metal, or an alloy of metals, or even an alloy of a metal and a noble metal. Preferentially, the nanowires are silver, gold, copper or nickel nanowires.

By silver nanowires, for example, it is meant that more than 80% of the nanowires are silver nanowires. For example, for so-called “silver” nanowires, 90% of the nanowires can be silver nanowires, and 10% of the nanowires can be nanowires of another metal, such as copper.

Advantageously, the mass per unit area of the nanowires is 10 mg/m² to 1 000 mg/m², more advantageously from 20 mg/m² to 400 mg/m², and further advantageously from 30 mg/m² to 50 mg/m², which enables the amount of material used to be reduced, in particular in the case of precious metals. The manufacturing cost is thereby reduced while offering a proper electrical conduction, and an efficient electromagnetic shielding.

Advantageously, the mean nanowire diameter is lower than 200 nm, and preferably lower than 100 nm, and the mean nanowire length is from 1 μm to 500 μm.

Advantageously, the protective layer ensures mechanical strength of the network of nanowires. Further, it can protect the nanowires from the atmosphere, and more particularly from chemical degradation risks, for example from oxidation or sulphidation reactions.

Advantageously, the first polymeric material is a polysiloxane, a polyepoxide, a polyacrylic or a polyurethane.

Advantageously, the second polymeric material is a polysiloxane, a polyepoxide, a polyacrylic or a polyurethane.

Advantageously, the electrically insulating layer and the protective layer have a thickness ranging from 1 μm to 5 000 μm, and preferably, from 1 μm to 1 000 μm.

Advantageously, the shielding structure is semi-transparent. It is possible to view the sensitive elements through the shielding structure.

The invention also relates to a support comprising a zone of electronic components to be protected and a ground track, covered with the shielding structure as defined above,

the electrically insulating layer covering at least the zone of electronic components to be protected,

the electromagnetic shielding film being disposed on the zone of electronic components and being extended to the ground track, so as to make contact with the ground track, the electromagnetic shielding film being electrically insulated from the zone of electronic components to be protected by the electrically insulating layer,

the protective layer covering the shielding film.

Advantageously, the support is an electronic board.

The invention also relates to a method for making an electromagnetic shielding structure on a support comprising a zone of electronic components to be protected and a ground track, said method comprising at least the following successive steps of:

a) providing a support comprising a zone of electronic components to be protected and a ground track,

b) forming an electrically insulating layer of a first polymeric material at least on the zone of electronic components,

c) forming an electrically conductive shielding film comprising at least 90 mass % of metal nanowires on the zone of electronic components to be protected and up to the ground track,

the formation of the film being made by depositing and drying a solution comprising the metal nanowires and a solvent,

d) forming a protective layer of a second polymeric material on the shielding film.

The solution comprising the nanowires is advantageously homogeneous, the nanowires are well dispersed in the solvent, which ensures quality of the percolating network formed after the solvent is evaporated.

Advantageously, the first polymeric material is a polysiloxane, a polyepoxide, a polyacrylic or a polyurethane.

Advantageously, the electrically insulating layer has a transmittance higher than 70% in the visible region. The sensitive elements to be protected are visible through the electrically insulating layer, which makes positioning of the shielding film easier. The polymeric material and the thickness of the electrically insulating layer will be chosen such that the electrically insulating layer has a determined transparency.

Advantageously, the second polymeric material is a polysiloxane, a polyepoxide, a polyacrylic or a polyurethane.

These polymers can be dispersed in solvents. Once they are dispersed in solution, their viscosity is lower and their deposition is made easier. Forming the layer can be made by dispersing the polymer in the solvent, by applying the solution onto a support and evaporating the solvent.

Advantageously, the electrically insulating layer and the protective layer are formed by a contactless deposition technique, such as a spraying deposition or a curtain coating.

The shielding film can be made through a mask or by a localised spraying deposition. Only the zone to be protected is covered, which limits nanowire consumption and manufacturing costs.

Very advantageously, such a method can be made at ambient temperature and at ambient pressure, which makes its implementation easier and allows the use of plastic or polymeric substrate.

By ambient temperature, it is meant a temperature in the order of 20-25° C. and by ambient pressure, it is meant a pressure in the order of 1 bar.

### BRIEF DESCRIPTION OF THE DRAWINGS

The present invention will be better understood based on the description that follows and the appended drawings in which:

FIG. 1 is a cross-section profile view of a support comprising a zone of components which is protected by an electromagnetic shielding structure according to a first embodiment of the invention,

FIG. 2 is a cross-section profile view of a support comprising a zone of components which is protected by an electromagnetic shielding structure according to a second embodiment of the invention,

FIG. 3 is a top view of a support comprising a zone of components which is not protected and two zones of components each protected by an electromagnetic shielding structure according to a third embodiment of the invention,

FIG. 4 is a top view of a support comprising two zones of components which are protected by a same electromagnetic shielding structure according to a fourth embodiment of the invention,

FIG. 5 is a cross-section profile view of a support comprising two zones of components which are protected by a same electromagnetic shielding structure according to a fifth embodiment of the invention,

FIG. 6 is a top view of an electrically conductive shielding film, according to a particular embodiment of the invention.

The different parts represented in the figures are not necessarily drawn to a uniform scale, to make the figures more readable.

The different possibilities (alternatives and embodiments) have to be understood as being non-exclusive to each other and can be combined to each other.

### DETAILED DISCLOSURE OF PARTICULAR EMBODIMENTS

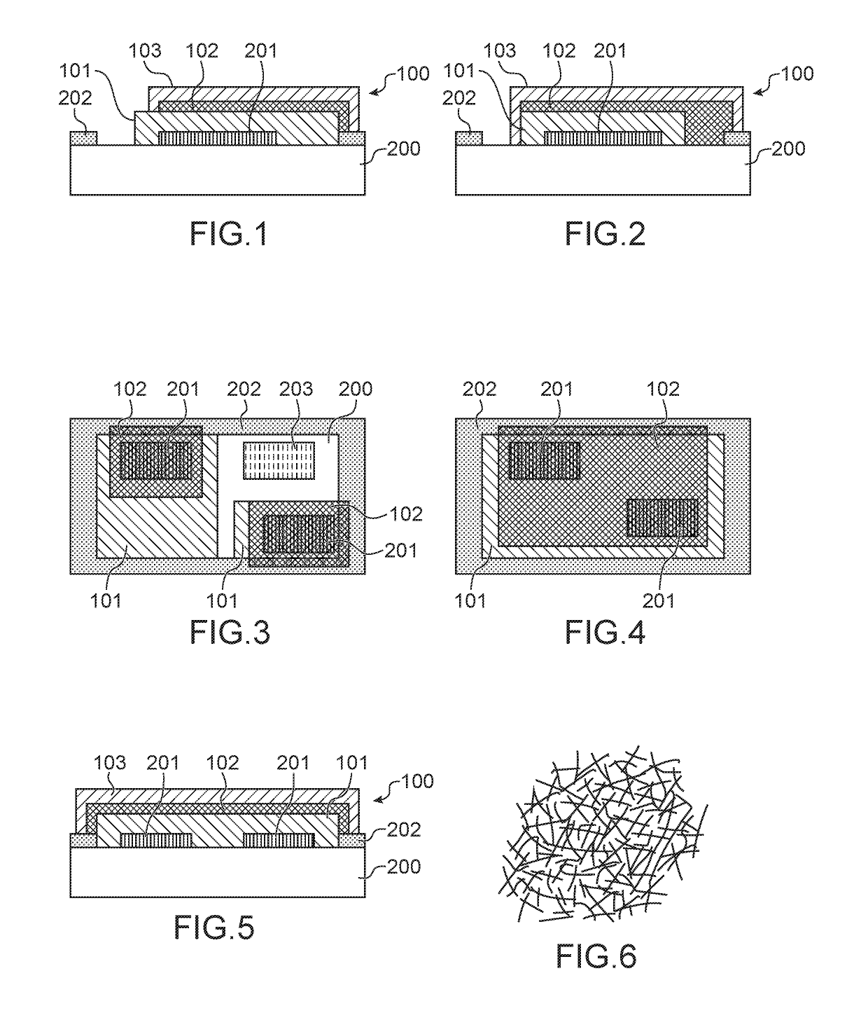

FIGS. 1 to 5 are first referred to, which represent an electromagnetic shielding structure 100 on a support 200 including at least one zone of so-called “sensitive” components 201, to be protected.

The Support 200:

The support 200 comprises components to be protected and a ground track 202.

The support 200 has, for example, a rectangular shape. However, it could have another shape, for example a square shape. The support 200 can be planar. According to an alternative, it is not planar, that is the support 200 has curvatures, level inequalities, regardless of the presence of the electronic components.

The support 200 is, for example, an electronic board. The components of the electronic board can for example be microprocessors, memories, input and output components, capacitors, resistors, converters, or buses. The components can be of the same size or different sizes.

The support 200 can include a single zone of components 201 to be protected (FIGS. 1, 2) or a plurality of zones of components to be protected (FIGS. 3, 4, 5). The zone to be protected can include a single component or a plurality of components. The zone of components 201 to be protected can represent an area of a few mm² or a few cm² depending on the number of components present in the zone. Sometimes, it is necessary to cover all the components of the support 200, which can constitute an area of a few dm².

The support can also include one or more zones of components which do not need to be protected 203 (FIG. 3).

Each zone 201 to be protected can be covered with its own shielding structure 100 (FIG. 3) or by a common shielding structure 100 (FIGS. 4 and 5). Each shielding structure 100 is connected to the ground track 202.

The ground track 202 is connected to the ground of the support 200. The ground track 202 is, for example, a metal ring, called a guard ring. The ground track 202 is, for example, of gold. As represented in FIGS. 1 to 5, the ground track 202 follows the entire perimeter of the support. It could, according to an alternative not represented, only follow part of the perimeter. In the different Figs., the ground track 202 is on the support 200, according to an alternative, it could be embedded in the support 200.

The Electromagnetic Shielding Structure 100

The electromagnetic shielding structure 100 is successively formed by:
an electrically insulating layer 101 of a first polymeric material,
an electrically conductive shielding film 102 comprising at least 90 mass % of metal nanowires,
a protective layer 103 of a second polymeric material.

The electromagnetic shielding structure 100 could contain additional layers. For example, it could possibly comprise two protective layers rather than a single one.

Preferentially, the shielding structure 100 consists of the electrically insulating layer 101, the shielding film 102 and the protective layer 103.

The electromagnetic shielding structure 100 has advantageously a transmittance, or transparency, higher than 50% in the visible region (from 350 nm to 750 nm), and preferably higher than 70%. This is called a semi-transparent layer. The structure 100 according to the invention enables components to be viewed unlike case-type shielding structures of prior art.

The Electrically Insulating Layer 101

The function of the layer 101 is to electrically insulate the components of the support 200 from the electrically conductive shielding film 102. The electrically insulating layer 101 can cover a single zone 201 of components (FIGS. 1, 2 and 3) or a plurality of zones 201 of components (FIGS. 4 and 5). It can also cover the entire support, except for the ground track 202.

The polymer forming the protective layer 101 is, for example, a polysiloxane (also called silicone), a polyacrylic, a polyurethane or a polyepoxide (also called epoxy).

The layer 101 has, for example, a thickness ranging from 1 μm to 5 000 μm and preferably, a thickness ranging from 1 μm to 1 000 μm to cover any type of components, of any geometrical shape, even those having reliefs, and those of a significant size.

The layer 101 of polymer has advantageously a transparency or transmittance higher than 70% in the visible region. It is possible to view the components through the layer 101, which enables the shielding film to be locally deposited onto the zone(s) to be protected.

The Electromagnetic Shielding Film 102

The electromagnetic shielding film 102 protects the electronic components of the support from electromagnetic interference. The shielding film 102 covers the zone 201 of electronic components to be protected and is extended to the ground track 202, so as to make contact with the ground track 202.

According to one embodiment represented in FIG. 1, the support 200 is not in contact with the shielding film 102, and the electrically insulating layer 101 is interposed between the support 200 and the shielding film 102.

According to an alternative represented in FIG. 2, a part of the support 200 can be in contact with the shielding film 102. This alternative is advantageously made, if the part of the support 200 in contact with the shielding film 102 is electrically insulating and/or if it does not include any components or electrical tracks.

The shielding film 102 can make contact with a part of the ground track 202 (FIGS. 1, 2, 3 and 4) or with the entire perimeter of the support 200 (FIG. 5).

The mass per unit area of the nanowires is from 10 mg/m² to 1 000 mg/m², and preferably from 20 mg/m² to 400 mg/m², and even more preferentially from 30 mg/m² to 50 mg/m² to allow an efficient shielding while being semi-transparent.

The nanowires can be silver, gold, nickel, or copper nanowires.

The mean nanowire diameter is advantageously lower than 200 nm, and further advantageously lower than 100 nm. The nanowire diameter is preferably from 15 nm to 200 nm, even more preferentially from 20 nm to 80 nm and yet even more preferentially from 40 nm to 80 nm. The mean nanowire length is advantageously from 1 μm to 500 μm, preferably the length ranges from 2 μm to 25 μm, and even more preferentially the length is in the order of 10 μm.

A schematic representation of a nanowire layer is given in FIG. 6. The nanowires form a percolating network commonly called a “two-dimensional network”, that is the nanowires are arranged such that they allow electron transport (system above the percolation threshold). The random network of metal nanowires form holes.

The shielding film 102 has, for example, a thickness from 20 nm to 1 000 nm, and preferably from 20 nm to 300 nm. It is possible to have locally N nanowires stacked on top of each other. The thickness of the corresponding shielding film 102 is N times the nanowire diameter.

The shielding film 102 can consist of metal nanowires.

The shielding film 102 can further comprise carbon nanotubes and/or graphene to improve the electrical conductivity.

The Protective Layer 103

The protective layer 103 ensures mechanical strength of the nanowires of the electromagnetic shielding film 102. It covers the electromagnetic film 102. It can fully cover it. Advantageously, an accessibility to the ground track 202 will be left. The protective layer is not represented in FIGS. 3 and 4 for the sake of legibility.

The protective layer 103 is of polysiloxane, of polyepoxide, of polyacrylic or of polyurethane. Advantageously, it plays the role of a diffusion barrier by protecting the nanowires from the atmosphere, in particular from dioxygen, and sulphur, which avoids oxidation or sulfidation thereof. Chemical degradation risks are thus limited and the electromagnetic shielding performance are improved. It is advantageously electrically insulating.

The protective layer 103 has a thickness ranging from 1 μm to 5 000 μm and, preferably, from 1 μm to 1 000 μm, and even more preferentially from 1 μm to 500 μm.

The protective layer 103 is semi-transparent.

A method for making a shielding structure will now be described. The electromagnetic shielding structure 100 is made on a support comprising a zone of electronic components to be protected 201 and a ground track 202.

During a first step, the electrically insulating layer 101 is formed at least on the zone of electronic components 201.

During a second step, the electrically conductive shielding film 102 is formed, over the electrically insulating layer 101, on the zone of electronic components 201 and up to the ground track 202.

The shielding film 102 is formed by depositing and drying a solution containing metal nanowires and a solvent. The solvent is preferentially chosen from water, an organic solvent and a mixture thereof. Preferentially, the solvent is chosen from water, an alcohol and a water/alcohol mixture. The alcohol has, for example, from 1 to 4 carbon atoms. According to an alternative, an organic solvent such as acetone, methyl ethyl ketone, dimethylsufoxide, n-methylpyrrolidone, cyclohexan, or pentane, is used.

Preferentially, the metal nanowires constitute from 0.01% to 50 mass % of the solution, more preferentially, they constitute from 0.1% to 20 mass % and, even more preferentially, from 0.5% to 10 mass % of the solution. Depending on the mass concentration used, and of the deposition conditions (flow rate, velocity, etc.), it is possible to make, in a single deposition, an electromagnetic shielding film comprising one or more thicknesses of nanowires.

The electromagnetic shielding film 102 can be locally formed on the zone of electronic components 201, for example, through a mask the openings of which leave the zones 201 of interest accessible or by a localised spraying deposition.

The method comprises a third step in which a protective layer 103 is formed on the shielding film 102.

The electrically insulating layer 101 and/or the protective layer 103 are advantageously formed by the liquid pathway. For example, the electrically insulating layer 101 and the protective layer 103 are formed by depositing and drying a solution containing a polymer, advantageously, dispersed in a solvent.

According to an alternative, the polymeric material, in solution, is replaced with a precursor of the polymeric material associated with a polymerisation initiator. By precursor of the polymeric material, it is meant monomers and/or oligomers and/or pre-polymers resulting in the formation of the polymer. The polymerisation initiator is, for example, a photoinitiator or a radical initiator. The layers 101 and 103 are formed by depositing, polymerising and drying the solution.

These layers are preferably deposited by a contactless deposition technique. The contactless deposition prevents the components of the support 200, which can have very various heights from being touched, in particular upon making the electrically insulating layer 101. This can be, for example, a spray coating or even any coating technique, such as curtain coating, flow-coating or spin-coating.

The method is, advantageously, made at ambient temperature and ambient pressure. The method is advantageously made under the air, and there is no need to work under controlled atmosphere.

However, it is possible to slightly heat the substrate (up to 100° C. at most and preferably up to 70° C. at most) upon depositing the layers 101 and 103 or upon depositing the shielding film 102.

### Illustrating and Non-Limiting Example of One Embodiment

The support 200 is an electronic board, comprising a zone of interest to be protected 201 and a guard ring 202. The electronic board is washed beforehand.

A polyacrylic layer is deposited onto the electronic board by spin-coating to form the insulating layer 101. This is an electrically insulating transparent varnish marketed by the company 3M under the Scotch® 1601 reference. A drying step is made at 90° C. for 60 s in order to evaporate residual solvent traces.

The zones which do not contain electronic components to be protected are covered with a mask. The mask is formed by plasticised adhesives and silicone beads.

A methanol solution containing silver nanowires (400 mg/L), formed as in the publication entitled “Improvements in purification of silver nanowires by decantation and fabrication of flexible transparent electrodes. Application to capacitive touch sensors”, Céline Mayousse and al., Nanotechnology 2013, 24, 215501, is then deposited through the mask by nebulisation to form the shielding film 102. The deposition is made with a density per unit area of the nanowires of 75 mg/m² (measured by atomic absorption). The deposition of silver nanowires is made on the zone of components to be protected and offset up to the guard ring enabling the shielding film to be grounded.

After drying for 30 minutes at 50° C., the protections are removed.

A polysiloxane resin, marketed by the company Isochem, under the Varnish 300-1 reference, is diluted in n-butanol, and deposited by spraying onto the nanowires. It is then heated at 70° C. during 2 hours, to form the protective layer 103. The thickness of the protective layer 103 is about 3 μm.

All three layers 101, 102, 103 have an overall transmittance of 72% in the visible spectrum, which enables all the elements present on the electronic board to be readily viewed.

An electromagnetic shielding structure 100 has been formed on a glass substrate in order to assess electromagnetic wave attenuation. The measurements have been made in an anechoic chamber. The sample is positioned at about 10 cm from a transmitter and at about 80 cm from a receiver. An attenuation of the signal (S21) of more than 30 dB has been measured on the entire range of 100 MHz-20 GHz.

1. An electromagnetic shielding structure successively comprising:
an electrically insulating layer of a first polymeric material,
an electrically conductive shielding film comprising at least 90 mass % of metal nanowires,
a protective layer of a second polymeric material.

2. The structure according to claim 1, wherein the mass per unit area of the nanowires is 10 mg/m² to 1 000 mg/m².

3. The structure according to claim 1, wherein the nanowires are silver, gold, nickel or copper nanowires.

4. The structure according to claim 1, wherein the mean nanowire diameter is lower than 200 nm, and the mean nanowire length is from 1 μm to 500 μm.

5. The structure according to claim 1, wherein the shielding film further comprises carbon nanotubes.

6. The structure according to claim 1, wherein the shielding film further comprises graphene.

7. The structure according to claim 1, wherein the shielding film consists of metal nanowires.

8. The structure according to claim 1, wherein the shielding film has a thickness ranging from 20 nm to 1 000 nm.

9. The structure according to claim 1, wherein the electromagnetic shielding structure has a transmittance higher than 50% in the visible region.

10. The structure according to claim 1, wherein the first polymeric material and the second polymeric material are chosen from a polysiloxane, a polyepoxide, a polyacrylic and a polyurethane.

11. The structure according to claim 1, wherein the electrically insulating layer and the protective layer have a thickness ranging from 1 μm to 5 000 μm.

12. A support comprising a zone of electronic components to be protected and a ground track, covered with a structure as defined in claim 1,
the electrically insulating layer covering at least the zone of electronic components to be protected,
the electromagnetic shielding film being disposed on the zone of electronic components and being extended to the ground track, so as to make contact with the ground track, the electromagnetic shielding film being electrically insulated from the zone of electronic components to be protected by the electrically insulating layer,
the protective layer covering the shielding film.

13. The support according to claim 12, the support being an electronic board.

14. A method for making an electromagnetic shielding structure, according to claim 1, on a support comprising a zone of electronic components to be protected and a ground track, said method comprising at least the following successive steps of:
a) providing a support comprising a zone of electronic components to be protected and a ground track,
b) forming an electrically insulating layer of a first polymeric material at least on the zone of electronic components,
c) forming an electrically conductive shielding film comprising at least 90 mass % of metal nanowires on the zone of electronic components to be protected and up to the ground track,
the formation of the film being made by depositing and drying a solution comprising the metal nanowires and a solvent,
d) forming a protective layer of a second polymeric material on the shielding film.

15. The method according to claim 14, wherein the electrically insulating layer and the protective layer are formed by a contactless deposition technique.

16. The method according to claim 14, wherein the first polymeric material and the second polymeric material are chosen from a polysiloxane, a polyepoxide, a polyacrylic and a polyurethane.

17. The method according to claim 14, wherein the electrically insulating layer has a transmittance higher than 70% in the visible region.

18. The method according to claim 14, wherein the shielding film is formed through a mask or by a localised spraying deposition.

19. The method according to claim 14, the method being made at ambient temperature and ambient pressure.
